(19) United States
(12) Patent Application Publication
(10) Pub. No.: US 2022/0385255 A1
(43) Pub. Date: Dec. 1, 2022

(54) APPARATUS AND METHOD FOR ADAPTIVELY CONTROLLING DYNAMIC RANGE

(71) Applicant: WELLANG CO., LTD., Gyeonggi-do (KR)

(72) Inventor: Yeongha CHOI, Seoul (KR)

(73) Assignee: WELLANG CO., LTD., Gyeonggi-do (KR)

(21) Appl. No.: 17/826,676

(22) Filed: May 27, 2022

(30) Foreign Application Priority Data
Jun. 1, 2021 (KR) 10-2021-0071087

(51) Int. Cl. H03G 3/30; H04R 3/00; H04R 29/00

(52) U.S. Cl. CPC H03G 3/301; H04R 3/00; H04R 29/001; H04R 2430/01; H03G 2201/103

(57) ABSTRACT

An audio processing apparatus configured to limit a dynamic range of an audio signal includes a variable gain amplifier configured to generate an output signal by amplifying or attenuating an input signal, a level detector configured to detect a level of the input signal or the output signal, and a gain controller configured to perform an attack and a release based on the level and a plurality of threshold values.

### CROSS-REFERENCE TO RELATED APPLICATION

This application is based on and claims priority under 35 U.S.C. § 119 to Korean Patent Application No. 10-2021-0071087, filed on Jun. 1, 2021, in the Korean Intellectual Property Office, the disclosure of which is incorporated by reference herein in its entirety.

### BACKGROUND

### 1. Field

One or more embodiments relate to audio processing, and more particularly, to an apparatus and method for adaptively controlling a dynamic range.

### 2. Description of the Related Art

A speaker may have a dynamic range, and, when receiving a signal having a magnitude greater than the dynamic range, the speaker may not normally output a sound or may even be damaged. Dynamic range control may be applied to prevent damage to the speaker and/or clipping of the signal. The signal provided to the speaker may be greater than the dynamic range due to various causes, such as a source signal including a value corresponding to a loud sound, and a user's volume control. Accordingly, dynamic range control, which limits a dynamic range while minimizing distortion of a sound output through a speaker, may be significant.

### SUMMARY

One or more embodiments include an apparatus and method for adaptively controlling a dynamic range to minimize distortion of a sound.

Additional aspects will be set forth in part in the description which follows and, in part, will be apparent from the description, or may be learned by practice of the presented embodiments of the disclosure.

According to one or more embodiments, an audio processing apparatus configured to limit a dynamic range of an audio signal includes: a variable gain amplifier configured to generate an output signal by amplifying or attenuating an input signal; a level detector configured to detect a level of the input signal or the output signal; and a gain controller configured to perform an attack and a release based on the level and a plurality of threshold values, wherein the gain controller is configured to: while performing the attack, identify a range to which the level belongs, from among a plurality of ranges defined by the plurality of threshold values; identify an attack intensity corresponding to the identified range, from among a plurality of attack intensities respectively corresponding to the plurality of ranges; and control a gain of the variable gain amplifier based on the identified attack intensity.

The plurality of threshold values may include a first threshold value and a second threshold value that is higher than the first threshold value, and a first attack intensity corresponding to a first range defined by the first threshold value may be lower than a second attack intensity corresponding to a second range that is defined by the second threshold value and is different from the first range.

The plurality of threshold values may include a first threshold value and a second threshold value that is higher than the first threshold value, and a first attack intensity corresponding to a first range defined by the first threshold value may be higher than a second attack intensity corresponding to a second range that is defined by the second threshold value and is different from the first range.

The audio processing apparatus may further include an interface unit configured to receive a control signal from the outside, wherein the gain controller sets, based on the control signal, at least one of the plurality of threshold values and the plurality of attack intensities.

The audio processing apparatus may further include a timer configured to measure an attack hold time, wherein the gain controller resets the timer when the attack starts, and starts the release when the attack hold time is measured.

The gain controller may reset the timer when the level is greater than a reference value that is lower than a lowest threshold value from among the plurality of threshold values, while the gain is reduced by the attack.

The level detector may detect the level that is proportional to an instantaneous peak of the input signal or the output signal.

According to one or more embodiments, an audio processing apparatus configured to limit a dynamic range of an audio signal includes: a variable gain amplifier configured to generate an output signal by amplifying or attenuating an input signal; a level detector configured to detect a level of the input signal or the output signal; and a gain controller configured to perform an attack and a release based on the level and predefined at least one function, wherein the gain controller is configured to, while performing the attack, calculate an attack intensity corresponding to the level, based on the at least one function, and control a gain of the variable gain amplifier based on the calculated attack intensity.

The gain controller may: while performing the attack, identify a range to which the level belongs, from among a plurality of ranges defined by a plurality of threshold values; identify a function corresponding to the identified range, from among a plurality of predefined functions respectively corresponding to the plurality of ranges; and calculate the attack intensity corresponding to the level, based on the identified function.

The audio processing apparatus may further include an interface unit configured to receive a control signal from the outside, wherein the gain controller sets at least one coefficient included in the at least one function, based on the control signal.

According to one or more embodiments, an audio processing apparatus configured to limit a dynamic range of an audio signal includes: a variable gain amplifier configured to generate an output signal by amplifying or attenuating an input signal; a level detector configured to detect a level of the input signal or the output signal; a timer configured to measure an attack hold time; and a gain controller configured to perform an attack and a release based on the level and at least one threshold value, wherein the gain controller resets the timer when the attack starts, and starts the release when the attack hold time is measured.

The audio processing apparatus may further include an interface unit configured to receive a control signal from the outside, wherein the gain controller sets at least one of the attack hold time and a reference value based on the control signal.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram illustrating an audio system including an audio processing apparatus, according to an example embodiment;

FIG. 2A is a block diagram illustrating one example of a dynamic range controller according to example embodiments;

FIG. 2B is a block diagram illustrating another example of a dynamic range controller according to example embodiments;

FIG. 3 is a view illustrating an example of a plurality of threshold values according to an example embodiment;

FIG. 4 is a flowchart illustrating a method of adaptively controlling a dynamic range, according to an example embodiment;

FIG. 5 is graphs illustrating an example of an attack operation according to an example embodiment;

FIG. 6A is one example of a waveform diagram illustrating examples of an output signal according to example embodiments;

FIG. 6B is another example of a waveform diagram illustrating examples of an output signal according to example embodiments;

FIG. 6C is further another example of a waveform diagram illustrating examples of an output signal according to example embodiments;

FIG. 7A is a flowchart illustrating one example of a method of adaptively controlling a dynamic range, according to example embodiments;

FIG. 7B is a flowchart illustrating another example of a method of adaptively controlling a dynamic range, according to example embodiments;

FIG. 8A is a graph illustrating one example of an attack operation according to example embodiments;

FIG. 8B is a graph illustrating another example of an attack operation according to example embodiments;

FIG. 8C is a graph illustrating further another example of an attack operation according to example embodiments;

FIG. 9A is a graph illustrating one example of dynamic range control;

FIG. 9B is a graph illustrating another example of dynamic range control;

FIG. 10A is a block diagram illustrating one example of a dynamic range controller according to example embodiments;

FIG. 10B is a block diagram illustrating another example of a dynamic range controller according to example embodiments;

FIG. 11 is a flowchart illustrating a method of adaptively controlling a dynamic range, according to an example embodiment;

FIG. 12A is a graph illustrating one example of a release operation according to example embodiments;

FIG. 12B is a graph illustrating one example of a release operation according to example embodiments;

FIG. 13 is a flowchart illustrating a method of adaptively controlling a dynamic range, according to an example embodiment;

FIG. 14A is a waveform diagram illustrating one example of an output signal for a same input signal, according to example embodiments;

FIG. 14B is a waveform diagram illustrating another example of an output signal for a same input signal, according to example embodiments;

FIG. 15 is a block diagram illustrating an example of an audio processing apparatus according to an example embodiment; and

FIG. 16 is a view illustrating an audio system according to an example embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

Hereinafter, example embodiments will be described in detail with reference to the accompanying drawings. The example embodiments are provided so that the disclosure will be thorough and complete, and will fully convey the concept of the disclosure to one of ordinary skill in the art. While the example embodiments are capable of various modifications and alternative forms, embodiments thereof are shown by way of example in the drawings and will herein be described in detail. It should be understood, however, that there is no intent to limit the example embodiments to the particular forms disclosed, but on the contrary, the example embodiments are to cover all modifications, equivalents, and alternatives falling within the scope of the disclosure. Like reference numerals refer to like elements throughout the description of the drawings. In the accompanying drawings, the dimensions of structures are more enlarged or reduced than actual dimensions for clarity of the disclosure.

The terminology used herein is for the purpose of describing particular embodiments only and is not intended to be limiting of example embodiments. The singular forms are intended to include the plural forms as well, unless the context clearly indicates otherwise. It will be further understood that the terms “comprise,” “comprising,” “include,” “including,” “have,” and/or “having” when used herein, specify the presence of stated features, integers, steps, operations, elements, components, and/or groups thereof, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

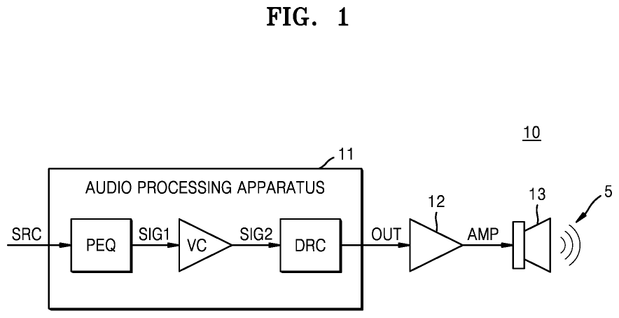

FIG. 1 is a block diagram illustrating an audio system 10 including an audio processing apparatus 11, according to an example embodiment. The audio system 10 may be referred to as a speaker system and, as a non-limiting example, may be a stationary apparatus, such as a television, a monitor, or a sound bar, may be a portable device, such as a mobile phone, a laptop computer, or a tablet, or may be a component included in the devices described above. As illustrated in FIG. 1, the audio system 10 may include the audio processing apparatus 11, an amplifier 12, and a speaker 13. In one or more embodiments, unlike being illustrated in FIG. 1, the audio system 10 may also include two or more speakers, and the two or more speakers may respectively receive signals from the audio processing apparatus 11 via the amplifier 12, or may respectively receive signals from two or more audio processing apparatuses via two or more amplifiers. Also, in one or more embodiments, additional elements (e.g., an LC filter and the like) may be further arranged on a path illustrated in FIG. 1.

The audio processing apparatus 11 may generate an output signal OUT by processing a source signal SRC, and may provide the output signal OUT to the amplifier 12. In one or more embodiments, the audio processing apparatus 11 may be an integrated circuit manufactured by a semiconductor process. As illustrated in FIG. 1, the audio processing apparatus 11 may include a parametric equalizer PEQ, a volume controller VC, and a dynamic range controller DRC. In one or more embodiments, the parametric equalizer PEQ and/or the volume controller VC may be omitted. In one or more embodiments, each of the elements of the audio processing apparatus 11 may be logic hardware designed by logic synthesis, a processing unit including a processor and software executed by the processor, or a combination of the logic hardware and the processing unit. In one or more embodiments, each of the elements of the audio processing apparatus 11 may include a circuit for processing an analog signal, e.g., an analog amplifier, analog filter, and/or analog limiter circuit.

The parametric equalizer PEQ may generate a first signal SIG1 by processing the source signal SRC. In one or more embodiments, the parametric equalizer PEQ may generate the first signal SIG1 by compensating for a frequency characteristic of the source signal SRC. In one or more embodiments, the parametric equalizer PEQ may generate, from the source signal SRC, the first signal SIG1 having the frequency characteristic adjusted by a user.

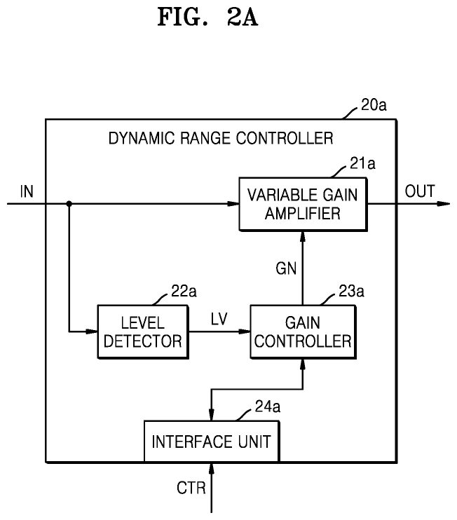

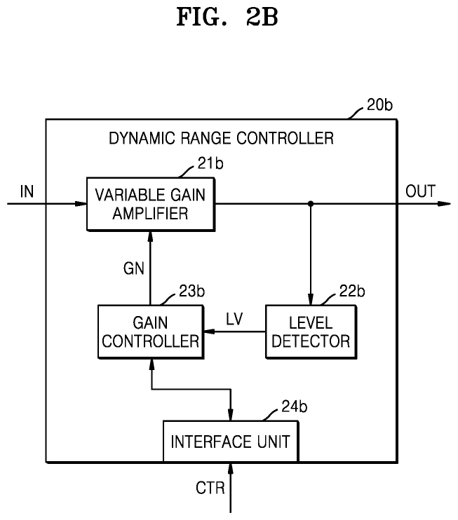

The volume controller VC may generate a second signal SIG2 by amplifying or attenuating the first signal SIG1 based on a volume. The volume may be set to adjust the loudness of a sound 5 output via the speaker 13, and the volume controller VC may amplify or attenuate the first signal SIG1 based on the set volume. Therefore, the volume controller VC may include an amplifier, or an operation block that performs amplification. In one or more embodiments, the volume may be set based on a signal (e.g., a control signal CTR of FIGS. 2A and 2B) received from the outside of the audio processing apparatus 11. In one or more embodiments, unlike being illustrated in FIG. 1, the volume controller VC may be omitted from the audio processing apparatus 11. For example, the loudness of the sound 5 output by the speaker 13 in the audio system 10 may rely on the source signal SRC, and the loudness of the sound 5 may be adjusted by adjusting the source signal SRC.

The dynamic range controller DRC may generate the output signal OUT by limiting a magnitude of the second signal SIG2 based on a dynamic range of the speaker 13. The amplifier 12 may amplify the output signal OUT provided from the audio processing apparatus 11, and the speaker 13 may convert, into the sound 5, an electrical signal provided from the amplifier 12, i.e., an amplified signal AMP, and may have a unique dynamic range. When a magnitude of the amplified signal AMP provided to the speaker 13 is greater than a dynamic range, the speaker 13 may output the distorted sound 5 or may even be damaged. The amplifier 12 may have a constant gain, and accordingly, the magnitude of the amplified signal AMP may rely on the magnitude of the output signal OUT. When the source signal SRC has a value corresponding to a loud sound, and/or a high volume is set by the volume controller VC, the second signal SIG2 may correspond to the amplified signal AMP, which is greater than the dynamic range of the speaker 13. The dynamic range controller DRC may generate the output signal OUT by limiting the magnitude of the second signal SIG2 based on the greatest magnitude of the second signal SIG2 for not being greater than the dynamic range of the speaker 13. An attack may refer to an operation in which the dynamic range controller DRC reduces a gain for amplifying or attenuating the second signal SIG2 to reduce the magnitude of the output signal OUT, and a release may refer to an operation in which the dynamic range controller DRC increases the gain to recover the reduced gain. As used herein, the second signal SIG2 input into the dynamic range controller DRC may be referred to as an input signal (e.g., an input signal IN of FIGS. 2A and 2B).

As will be described below with reference to the drawings, the dynamic range controller DRC may adaptively control a dynamic range. For example, the dynamic range controller DRC may generate the output signal OUT by attenuating the second signal SIG2 according to the magnitude of the second signal SIG2, and accordingly, distortion of the output signal OUT may be reduced. In addition, the dynamic range controller DRC may minimize the distortion of the output signal OUT by delaying the recovery of the gain while omitting an unneeded attack that is subsequent to a short pulse of the second signal SIG2 having a high amplitude.

FIGS. 2A and 2B are block diagrams illustrating examples of a dynamic range controller according to example embodiments. In detail, the block diagram of FIG. 2A illustrates a dynamic range controller 20a having a feed-forward structure, and the block diagram of FIG. 2B illustrates a dynamic range controller 20b having a feedback structure. As described above with reference to FIG. 1, the dynamic range controllers 20a and 20b may receive an input signal IN, and may generate an output signal OUT by limiting a dynamic range of the input signal IN. Hereinafter, the same descriptions of FIGS. 2A and 2B will be omitted.

Referring to FIG. 2A, the dynamic range controller 20a may adjust a magnitude of the output signal OUT based on a level of the input signal IN. As illustrated in FIG. 2A, the dynamic range controller 20a may include a variable gain amplifier 21a, a level detector 22a, a gain controller 23a, and an interface unit 24a. In one or more embodiments, the interface unit 24a may be omitted.

The variable gain amplifier 21a may generate the output signal OUT by amplifying or attenuating the input signal IN based on a gain signal GN provided from the gain controller 23a. In one or more embodiments, the variable gain amplifier 21a may include a digital amplifier, and may receive a digital signal as the gain signal GN from the gain controller 23a. In one or more embodiments, the variable gain amplifier 21a may include an analog amplifier, and may receive an analog signal and/or a digital signal as the gain signal GN from the gain controller 23a.

The level detector 22a may detect the level of the input signal IN, and may provide the gain controller 23a with a level signal LV corresponding to the detected level. In one or more embodiments, the level detector 22a may detect an instantaneous peak of the input signal IN instead of using an envelope, a moving average, or the like of the input signal IN, and may provide the gain controller 23a with the level signal LV corresponding to the detected instantaneous peak.

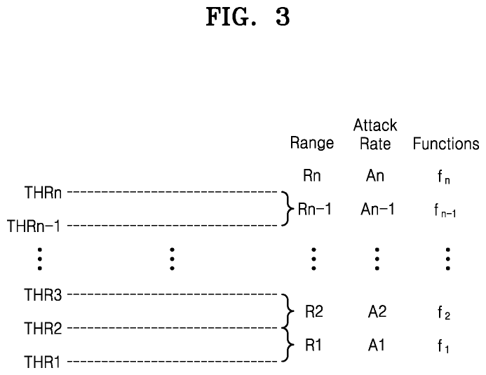

The gain controller 23a may receive the level signal LV from the level detector 22a, and may provide the gain signal GN to the variable gain amplifier 21a. The gain controller 23a may identify the level of the input signal IN based on the level signal LV, and may generate the gain signal GN based on the identified level and a plurality of threshold values. In one or more embodiments, the gain controller 23a may include a memory for storing a plurality of threshold values and/or a plurality of attack intensities, a plurality of functions, and the like, which will be described later with reference to FIG. 3, or may access an external memory. For example, the gain controller 23a may include or access a non-volatile memory, e.g., a flash memory or the like, so that information is not lost even when a power supply is cut off. Examples of an operation of the gain controller 23a will be described later with reference to FIGS. 3, 4, 7A, and 7B.

The interface unit 24a may receive a control signal CTR from the outside of the dynamic range controller 20a or the outside of an audio system including the dynamic range controller 20a. For example, the interface unit 24a may form a wired communication channel, such as a universal serial bus (USB) or RS232, with an external device, or may form a wireless communication channel, such as Bluetooth, WiFi, or near field communication (NFC), with the external device. A user of the dynamic range controller 20a, e.g., a manufacturer or user of an audio system, may set an operation of the gain controller 23a via the control signal CTR based on a dynamic range of a speaker. For example, a plurality of threshold values referred to by the gain controller 23a may be set based on the control signal CTR received via the interface unit 24a.

Referring to FIG. 2B, the dynamic range controller 20b may adjust a magnitude of the output signal OUT based on a level of the output signal OUT. As illustrated in FIG. 2B, the dynamic range controller 20b may include a variable gain amplifier 21b, a level detector 22b, a gain controller 23b, and an interface unit 24b. In one or more embodiments, the interface unit 24b may be omitted.

The level detector 22b may detect the level of the output signal OUT, and may provide the gain controller 23b with a level signal LV corresponding to the detected level. While the level of the input signal IN is detected in the feed-forward type of dynamic range controller 20a described above with reference to FIG. 2A, the level of the output signal OUT may be detected in the feedback type of dynamic range controller 20b illustrated in FIG. 2B. The gain controller 23b may generate a gain signal GN based on the level signal LV, and the variable gain amplifier 21b may generate the output signal OUT by amplifying or attenuating the input signal IN based on the gain signal GN. Hereinafter, example embodiments will be described mainly with reference to the feed-forward type of dynamic range controller 20a of FIG. 2A, but may also be applied to the feedback type of dynamic range controller 20b of FIG. 2B.

FIG. 3 is a view illustrating an example of a plurality of threshold values according to an example embodiment. As described above with reference to FIGS. 2A and 2B, the gain controller 23a or 23b may control a gain of the variable gain amplifier 21a or 21b with reference to a plurality of threshold values. Hereinafter, FIG. 3 will be described with reference to FIG. 2A.

Referring to FIG. 3, first to n^{th} threshold values THR1 to THRn (n is an integer greater than 1) may be referred to by the gain controller 23a. For example, when the input signal IN is greater than the lowest first threshold value THR1 from among the first to n^{th} threshold values THR1 to THRn, gain control for limiting a dynamic range, e.g., an attack, may be performed. When the input signal IN is less than the first threshold value THR1, the attack may not be performed.

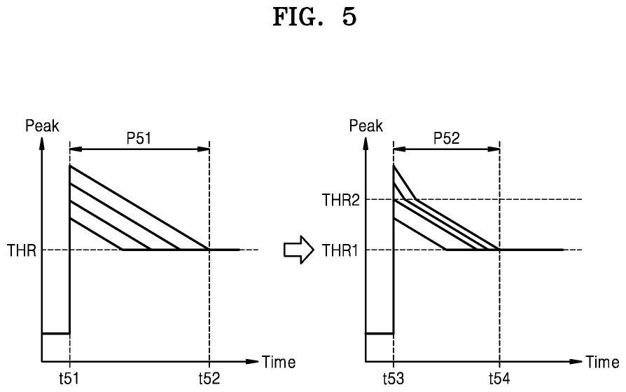

In one or more embodiments, first to n^{th} ranges R1 to Rn may be defined by the first to n^{th} threshold values THR1 to THRn, and first to n^{th} attack intensities A1 to An respectively corresponding to the first to n^{th} ranges R1 to Rn may be referred to by the gain controller 23a. For example, as illustrated in FIG. 3, the first range R1 may be defined between the first threshold value THR1 and the second threshold value THR2, and the first range R1 may correspond to the first attack intensity A1. An attack intensity may refer to a level of an attack applied in dynamic range control. For example, an attack intensity may include a rate of decrease in a gain, and a high attack intensity may correspond to a high rate of decrease in the gain. In addition, the attack intensity may include an attack time for which a decrease in the gain occurs, and the high attack intensity may correspond to a short attack time (i.e., a radical decrease in the gain). Hereinafter, while an attack rate will be mainly referred to as an example of an attack intensity, it will be understood that example embodiments may be applied to any attack intensity corresponding to a level of an attack. In one or more embodiments, the first to n^{th} attack intensities A1 to An may be different from one another, and accordingly, as will be described later with reference to FIG. 5 and the like, a dynamic range of the input signal IN may be more efficiently limited than when a single threshold value (e.g., the first threshold value THR1) is used. Hereinafter, example embodiments will be described with reference to FIG. 3.

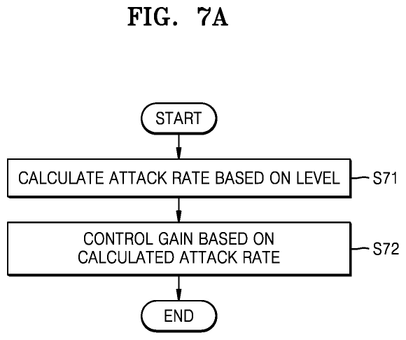

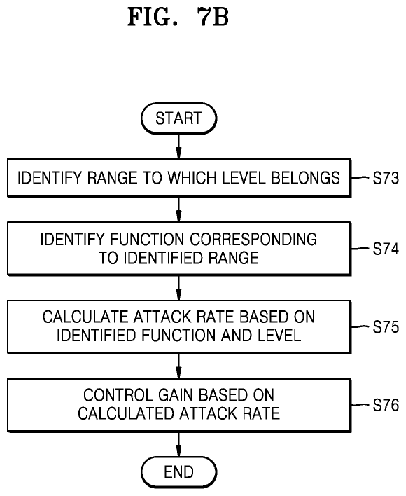

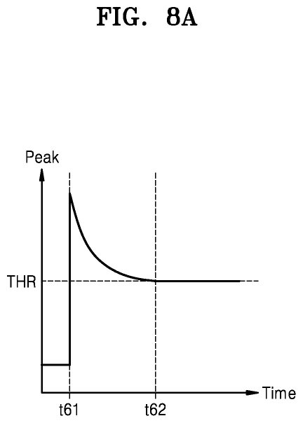

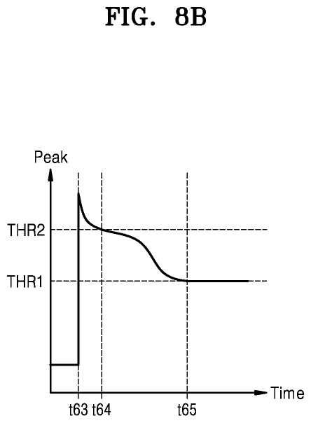

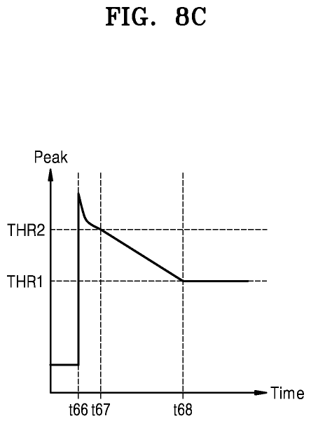

In one or more embodiments, the first to n^{th} ranges R1 to Rn may be defined by the first to n^{th} threshold values THR1 to THRn, and first to n^{th} functions f₁ to fₙ respectively corresponding to the first to n^{th} ranges R1 to Rn may be referred to by the gain controller 23a. For example, as illustrated in FIG. 3, the first range R1 between the first threshold value THR1 and the second threshold value THR2 may correspond to the first function Each of the first to n^{th} functions f₁ to fₙ may have a level of the input signal IN as an input, and may have an attack intensity as an output. In one or more embodiments, the first to n^{th} functions f₁ to fₙ may be different from one another. In one or more embodiments, each of the first to n^{th} functions f₁ to fₙ may be any one-to-one function for a level that is greater than or equal to a threshold value, e.g., may be a constant function, an exponential function, a linear function, a square function, a cubic function, or the like. For example, an example in which each of the first to n^{th} functions f₁ to fₙ is a constant function may be the same as the above-described example in which the first to n^{th} attack intensities A1 to AN respectively corresponding to the first to n^{th} ranges R1 to Rn are present (e.g., f₁=A1). In one or more embodiments, as will be described later with reference to FIGS. 7A and 8A, one function may also be used in one range defined by one threshold value.

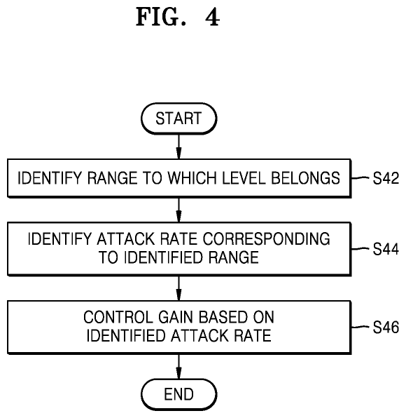

FIG. 4 is a flowchart illustrating a method of adaptively controlling a dynamic range, according to an example embodiment. As illustrated in FIG. 4, the method of adaptively controlling a dynamic range may include a plurality of operations S42, S44, and S46. In one or more embodiments, the method of FIG. 4 may be performed by the gain controller 23a of FIG. 2A. Hereinafter, FIG. 4 will be described with reference to FIG. 2A.

Referring to FIG. 4, in operation S42, a range to which a level belongs may be identified. For example, the gain controller 23a may identify a level of the input signal IN based on the level signal LV received from the level detector 22a. The gain controller 23a may identify, from among a plurality of ranges defined by a plurality of threshold values, the range to which the level belongs by identifying a threshold value that is less than the identified level and a threshold value that is greater than the identified level.

In operation S44, an attack rate corresponding to the identified range may be identified. For example, as described above with reference to FIG. 3, a plurality of attack rates respectively corresponding to a plurality of ranges may be present, and the gain controller 23a may identify, from among the plurality of attack rates, an attack rate corresponding to the range identified in operation S42.

In operation S46, a gain may be controlled based on the identified attack rate. For example, the gain controller 23a may generate the gain signal GN, such that the gain decreases according to the attack rate identified in operation S44.

FIG. 5 is graphs illustrating examples of an attack operation according to an example embodiment. In detail, the left graph of FIG. 5 illustrates an attack operation based on a single threshold value THR, and the right graph of FIG. 5 illustrates an attack operation based on two threshold values THR1 and THR2. The graphs of FIG. 5 illustrate that peak values of output signals having various magnitudes overlap each other. Hereinafter, FIG. 5 will be described with reference to FIG. 3.

Referring to the left graph of FIG. 5, the output signal OUT may be greater than a threshold value THR at a time t51. A constant attack rate may be applied, and, as illustrated on the left graph of FIG. 5, a magnitude of an output signal OUT may decrease at a constant slope according to the constant attack rate. An output signal OUT having the greatest magnitude may reach the threshold value THR at a time t52, and accordingly, an attack may be performed during a period P51.

Referring to the right graph of FIG. 5, at a time t53, an output signal OUT may be greater than a first threshold value THR1 or a second threshold value THR2. When the output signal OUT is greater than the first threshold value THR1, similar to the left graph of FIG. 5, a magnitude of the output signal OUT may decrease at a constant slope according to the first attack intensity A1 corresponding to the first range R1 between the first threshold value THR1 and the second threshold value THR2. In contrast, when the output signal OUT is greater than the second threshold value THR2, the magnitude of the output signal OUT may decrease at a constant slope according to the second attack intensity A2 corresponding to the second range R2 between the second threshold value THR2 and the third threshold value THR3. When the output signal OUT falls below the second threshold value THR2, the magnitude of the output signal OUT may decrease at a constant slope according to the first attack intensity A1 corresponding to the first range R1. In one or more embodiments, the second attack intensity A2 may be higher than the first attack intensity A1, and accordingly, as illustrated on the right graph of FIG. 5, the magnitude of the output signal OUT may reach the first threshold value THR1 at a time t54. In other words, a period P52 may be shorter than the period P51, and as a result, a dynamic range may be limited early.

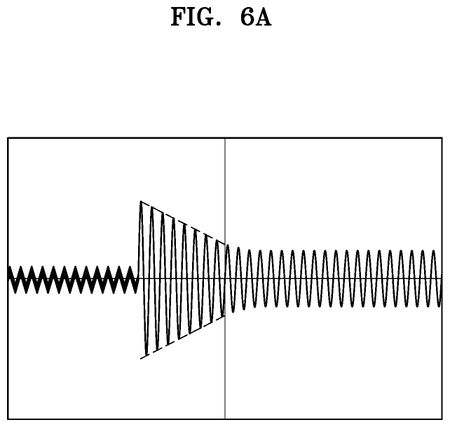

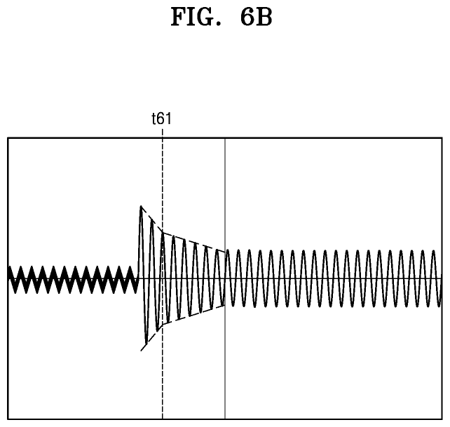

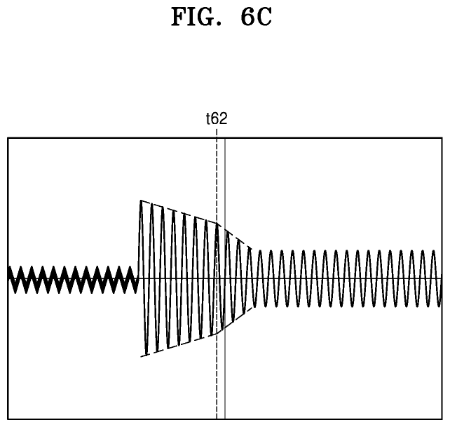

FIGS. 6A to 6C are waveform diagrams illustrating examples of an output signal according to example embodiments. In detail, the waveform diagram of FIG. 6A illustrates an output signal when a single threshold value is used, and the waveform diagrams of FIGS. 6B and 6C respectively illustrate output signals when two threshold values are used. Hereinafter, FIGS. 6A to 6C will be described with reference to FIG. 3.

Referring to FIG. 6A, the input signal IN may be greater than a single threshold value, and accordingly, an magnitude of the output signal OUT may also increase. Due to a constant attack intensity, the magnitude of the output signal OUT may constantly decrease, as indicated by a dotted line in FIG. 6A.

Referring to FIG. 6B, the input signal IN may be greater than the second threshold value THR2 as well as the first threshold value THR1. The second attack intensity A2 corresponding to the second range R2 may be higher than the first attack intensity A1 corresponding to the first range R1, and accordingly, as indicated by a dotted line in FIG. 6B, the magnitude of the output signal OUT may decrease relatively quickly until a time t61 and then decrease

relatively slowly from the time t61.

Referring to FIG. 6C, the input signal IN may be greater than the second threshold value THR2 as well as the first threshold value THR1. The second attack intensity A2 corresponding to the second range R2 may be lower than the first attack intensity A1 corresponding to the first range R1, and accordingly, as indicated by a dotted line in FIG. 6C, the magnitude of the output signal OUT may decrease relatively slowly until a time t62 and then decrease relatively quickly from the time t62.

FIGS. 7A and 7B are flowcharts illustrating examples of a method of adaptively controlling a dynamic range, according to example embodiments. In one or more embodiments, the method of FIG. 7A and the method of FIG. 7B may be performed by the gain controller 23a of FIG. 2A. Hereinafter, FIGS. 7A and 7B will be described with reference to FIG. 2A. The same descriptions of FIGS. 7A and 7B will be omitted herein.

Referring to FIG. 7A, the method of adaptively controlling a dynamic range may include operation S71 and operation S72. In operation S71, an attack rate may be calculated based on a level. For example, the gain controller 23a may identify a level of the input signal IN based on the level signal LV received from the level detector 22a. The gain controller 23a may calculate the attack rate from the level of the input signal IN based on a predefined function. As described above with reference to FIG. 3, the predefined function may be any one-to-one function for a level that is higher than or equal to a threshold value. In one or more embodiments, the function may include at least one coefficient, and the at least one coefficient may be set by the control signal CTR received via the interface unit 24a. In one or more embodiments, the function may be a monotonically increasing function in which an attack rate increases with an increase in the level of the input signal IN.

In operation S72, a gain may be controlled based on the calculated attack rate. For example, the gain controller 23a may generate the gain signal GN, such that the gain decreases according to the attack rate calculated in operation S71. An example of an attack operation according to the method of FIG. 7A will be described later with reference to FIG. 8A.

Referring to FIG. 7B, the method of adaptively controlling a dynamic range may include a plurality of operations S73 to S76. In operation S73, a range to which a level belongs may be identified. For example, the gain controller 23a may identify the level of the input signal IN based on the level signal LV received from the level detector 22a. The gain controller 23a may identify, from among a plurality of ranges defined by a plurality of threshold values, the range to which the level belongs by identifying a threshold value that is less than the identified level and a threshold value that is greater than the identified level.

In operation S74, a function corresponding to the identified range may be identified. For example, as described above with reference to FIG. 3, a plurality of functions respectively corresponding to a plurality of ranges may be predefined, and the gain controller 23a may identify, from among the plurality of functions, a function corresponding to the range identified in operation S73.

In operation S75, an attack rate may be calculated based on the identified function and level. For example, the gain controller 23a may calculate the attack rate from the level of the input signal IN, based on the function identified in operation S74.

In operation S76, a gain may be controlled based on the calculated attack rate. For example, the gain controller 23a may generate the gain signal GN, such that the gain decreases according to the attack rate calculated in operation S75. An example of an attack operation according to the method of FIG. 7B will be described later with reference to FIGS. 8B and 8C.

FIGS. 8A to 8C are graphs illustrating examples of an attack operation according to example embodiments. In detail, the graph of FIG. 8A illustrates an attack operation based on the method of FIG. 7A, and the graphs of FIGS. 8B and 8C illustrate an attack operation based on the method of FIG. 7B. Hereinafter, FIGS. 8A to 8C will be described with reference to FIGS. 7A and 7B.

Referring to FIG. 8A, the output signal OUT may be greater than a threshold value THR at a time t61. As described above with reference to FIG. 7A, an attack intensity corresponding to the level of the input signal IN may be calculated according to a predefined function. In one or more embodiments, the function may be a monotonically increasing function. For example, as illustrated in FIG. 8A, the attack intensity may decrease with a decrease in a level of the output signal OUT. Accordingly, the output signal OUT may decrease to the threshold value THR at a time t62, and similar to that described above with reference to FIG. 5, a dynamic range may be limited early.

Referring to FIG. 8B, at a time t63, the output signal OUT may be greater than a first threshold value THR1 or a second threshold value THR2. When the output signal OUT is greater than the second threshold value THR2, an attack intensity may be calculated based on the second function f₂ corresponding to the second range R2. At a time t64, the output signal OUT may fall below the second threshold value THR2, and the attack intensity may be calculated based on the first function f₁ corresponding to the first range R1. The output signal OUT may decrease to the first threshold value THR1 at a time t65.

Referring to FIG. 8C, at a time t66, the output signal OUT may be greater than the first threshold value THR1 or the second threshold value THR2. When the output signal OUT is greater than the second threshold value THR2, an attack intensity may be calculated based on the second function f₂ corresponding to the second range R2. At a time t67, the output signal OUT may fall below the second threshold value THR2, and the attack intensity may be calculated based on the first function f₁ corresponding to the first range R1. In the example of FIG. 8C, the second function f₂ may be a linear function, and the first function f₁ may be a constant function. The output signal OUT may decrease to the first threshold value THR1 at a time t68.

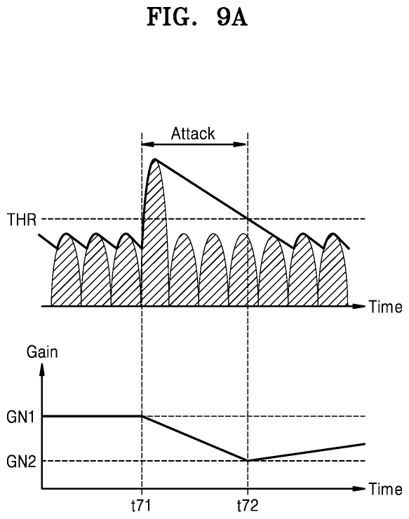

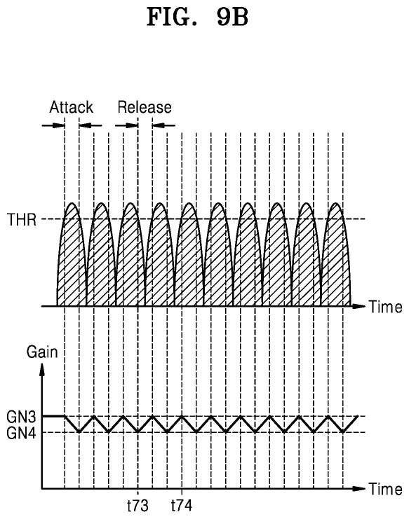

FIGS. 9A and 9B are graphs illustrating examples of dynamic range control. In detail, FIG. 9A illustrates an example of controlling a gain based on envelope detection, and FIG. 9B illustrates an example of controlling a gain based on an instantaneous peak. As illustrated in FIGS. 9A and 9B, the input signal IN may be converted via radio wave rectification, an absolute value, squaring, or the like to have a positive value, and hereinafter, a signal converted into a positive value may be simply referred to as the input signal IN.

Referring to FIG. 9A, an envelope may be detected from the input signal IN, and, when the detected envelope is greater than a threshold value THR, an attack may be performed. For example, as illustrated in FIG. 9A, due to a high magnitude input occurring at a time t71, the envelope may be greater than the threshold value THR, and accordingly, a gain may start to decrease from a first gain GN1. Despite the reduced magnitude of the input, the envelope may decrease slowly, and thus, the envelope may intersect the threshold value THR at a time t72. Accordingly, the decrease in the gain may end at the time t72, and the gain may gradually increase from a second gain GN2. As a result, an unneeded attack may occur, and thus, distortion of a signal may be induced.

Referring to FIG. 9B, the input may be directly compared with the threshold value THR, and, when the input is greater than the threshold value THR, an attack may be performed. For example, as illustrated in FIG. 9B, the attack may be performed whenever the input is greater than the threshold value THR, and a release may be performed whenever the input falls below the threshold value THR. Accordingly, a gain may vary frequently between a third gain GN3 and a fourth gain GN4, and as a result, distortion of the input, e.g., degradation of total harmonic distortion (THD), may occur. Unlike being illustrated in FIG. 9B, when a release intensity (e.g., a rate of increase in a gain and/or a release time) is lower than an attack intensity (e.g., a rate of decrease in the gain), the gain may also gradually decrease over time. As will be described hereinafter with reference to the drawings, dynamic range control according to an example embodiment may solve the issues described above with reference to FIGS. 9A and 9B.

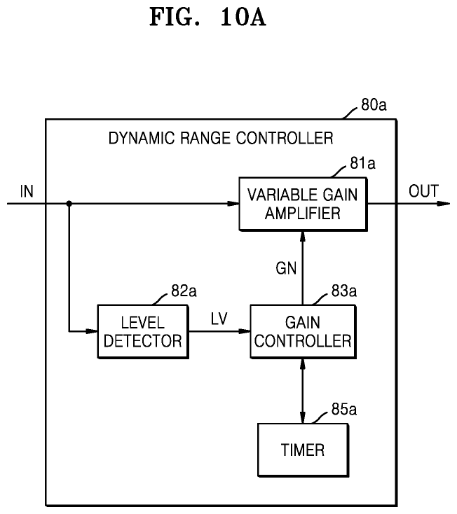

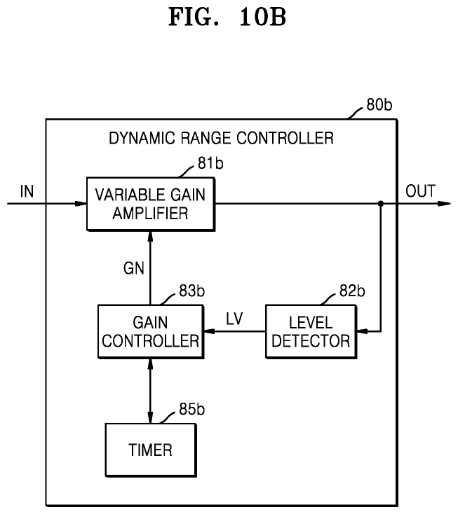

FIGS. 10A and 10B are block diagrams illustrating examples of a dynamic range controller according to example embodiments. In detail, the block diagram of FIG. 10A illustrates a dynamic range controller 80a having a feed-forward structure, and the block diagram of FIG. 10B illustrates a dynamic range controller 80b having a feedback structure. As described above with reference to FIG. 1, the dynamic range controllers 80a and 80b may receive an input signal IN, and may generate an output signal OUT by limiting a dynamic range of the input signal IN. Hereinafter, the same descriptions of FIGS. 10A and 10B, and the same description thereof as that of FIGS. 2A and 2B will be omitted.

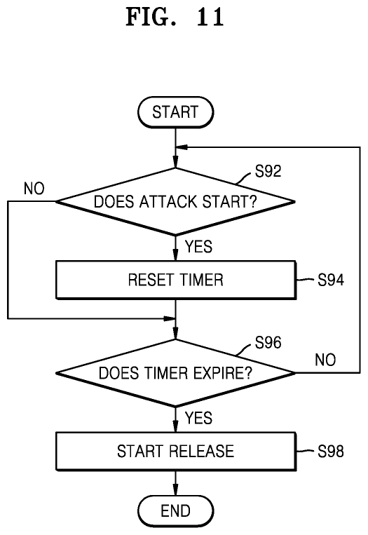

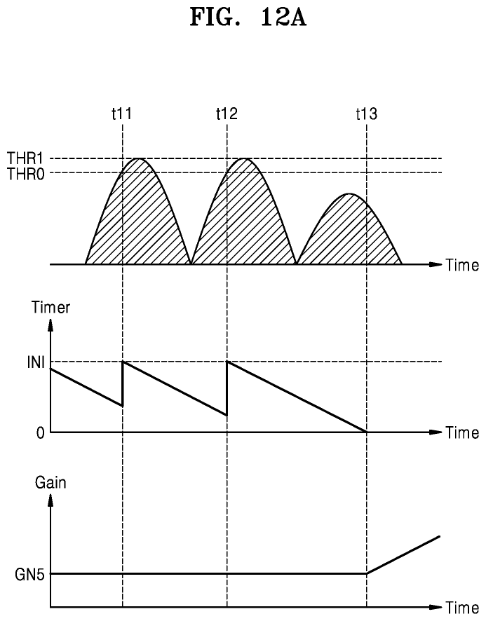

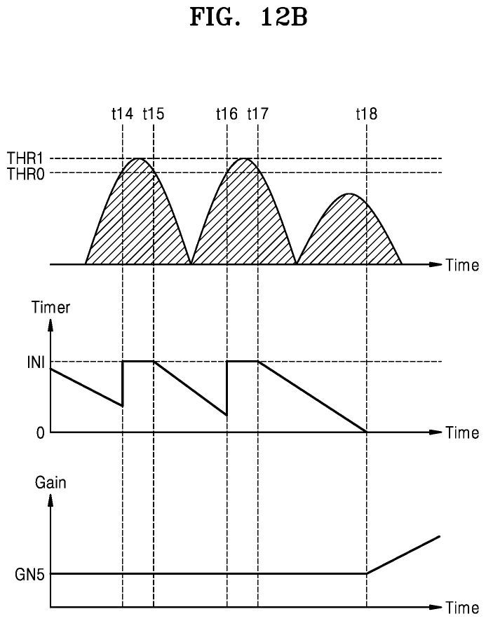

Referring to FIG. 10A, the dynamic range controller 80a may adjust a magnitude of the output signal OUT based on a level of the input signal IN. As illustrated in FIG. 10A, the dynamic range controller 80a may include a variable gain amplifier 81a, a level detector 82a, a gain controller 83a, and a timer 85a. In one or more embodiments, the dynamic range controller 80a may also further include the interface unit 24a of FIG. 2A. The timer 85a may measure an attack hold time. As will be described later with reference to FIGS. 11, 12A, and 12B, the attack hold time may refer to the least time needed from the start of an attack until the start of a release. Accordingly, the release may not start before the attack hold time elapses after the attack starts, and as a result, the release may be delayed. In one or more embodiments, the attack hold time may be set to about 25 ms based on a frequency of about 40 Hz obtained by half-wave rectification of the lowest audible frequency of about 20 Hz. In one or more embodiments, the timer 85a may include a counter, e.g., an up-counter or a down-counter, and the counter may be reset by the gain controller 83a.

The gain controller 83a may identify whether or not the attack hold time elapses, based on the timer 85a, and may control a gain of the variable gain amplifier 81a. For example, the gain controller 83a may reset the timer 85a, and may identify the elapse of the attack hold time based on expiration of the timer 85a. Accordingly, an unneeded attack, which is subsequent to a short pulse having a great amplitude, described above with reference to FIG. 9A, may be omitted, and simultaneously, degradation of THD described above with reference to FIG. 9B may be prevented.

Referring to FIG. 10B, the dynamic range controller 80b may adjust a magnitude of the output signal OUT based on a level of the output signal OUT. As illustrated in FIG. 10B, the dynamic range controller 80b may include a variable gain amplifier 81b, a level detector 82b, a gain controller 83b, and a timer 85b. In one or more embodiments, the dynamic range controller 80b may also further include the interface unit 24b of FIG. 2B.

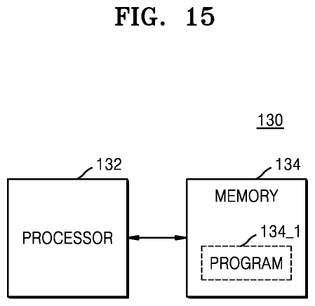

The level detector 82b may detect the level of the output signal OUT, and may provide the gain controller 83b with a level signal LV corresponding to the detected level. While the level of the input signal IN is detected in the feed-forward type of dynamic range controller 80a described above with reference to FIG. 10A, the level of the output signal OUT may be detected in the feedback type of dynamic range controller 80b illustrated in FIG. 10B. The gain controller 83b may generate a gain signal GN based on the level signal LV, and the variable gain amplifier 81b may generate the output signal OUT by amplifying or attenuating the input signal IN based on the gain signal GN. Also, the gain controller 83b may identify whether or not an attack hold time elapses, based on the timer 85b, and may generate the gain signal GN. Accordingly, an unneeded attack, which is subsequent to a short pulse having a great amplitude, described above with reference to FIG. 9A, may be omitted, and simultaneously, degradation of THD described above with reference to FIG. 9B may be prevented. Hereinafter, example embodiments will be described mainly with reference to the feed-forward type of dynamic range controller 80a of FIG. 10A, but may also be applied to the feedback type of dynamic range controller 80b of FIG. 10B. Examples of an operation of the gain controller 83a of FIG. 10A will be described later with reference to FIGS. 11 and 15.

FIG. 11 is a flowchart illustrating a method of adaptively controlling a dynamic range, according to an example embodiment. As illustrated in FIG. 11, the method of adaptively controlling a dynamic range may include a plurality of operations S92, S94, S96, and S98. In one or more embodiments, the method of FIG. 11 may be performed by the gain controller 83a of FIG. 10A. Hereinafter, FIG. 11 will be described with reference to FIG. 10A.

Referring to FIG. 11, in operation S92, whether or not an attack starts may be determined. For example, the gain controller 83a may identify a level of the input signal IN based on the level signal LV provided from the level detector 82a, and, when the identified level intersects the first threshold value THR1 and is greater than the first threshold THR1, may start the attack. As illustrated in FIG. 11, when the attack starts, operation S94 may be subsequently performed. When the attack does not start, operation S96 may be subsequently performed.

When the attack starts, in operation S94, the timer 85a may be reset. For example, when the attack starts, the gain controller 83a may reset the timer 85a, and accordingly, the timer 85a may count an attack hold time again from the beginning. In one or more embodiments, the reset of the timer 85a may be maintained for a certain period of time. For example, the gain controller 83a may maintain the reset of the timer 85a until the attack ends, and, when the attack ends, may release the reset of the timer 85a. Accordingly, the attack hold time may be measured from a point in time when the attack ends.

In operation S96, whether or not the timer 85a expires may be determined. For example, the timer 85a may expire when the attack hold time is measured, and may provide the gain controller 83a with a signal indicating the expiration thereof. The gain controller 83a may identify whether or not the attack hold time elapses, based on the signal provided from the timer 85a. As illustrated in FIG. 11, when the timer 85a expires, operation S98 may be subsequently performed. When the timer 85a does not expire, i.e., when the attack hold time does not elapse, operation S92 may be performed again.

When the timer 85a expires, a release may start in operation S98. For example, the gain controller 83a may identify the elapse of the attack hold time based on the signal provided from the timer 85a, and may start the release. Accordingly, a gain of the variable gain amplifier 81a may gradually increase. As a result, frequent switches of the attack and the release may be prevented, and accordingly, the issues described above with reference to FIG. 9B may be solved.

FIGS. 12A and 12B are graphs illustrating examples of a release operation according to example embodiments. In detail, in FIGS. 12A and 12B, the upper graphs illustrate a signal converted from the input signal IN and threshold values THR0 and THR1, the middle graphs illustrate a value of the timer 85a of FIG. 10A, and the lower graphs illustrate a gain of the variable gain amplifier 81a. Similar to FIGS. 9A and 9B, in FIGS. 12A and 12B, the input signal IN may be converted via radio wave rectification, an absolute value, squaring, or the like to have a positive value, and hereinafter, a signal converted into a positive value may be simply referred to as the input signal IN. Hereinafter, FIGS. 12A and 12B will be described with reference to FIG. 10A, and the same descriptions of FIGS. 12A and 12B will be omitted.

In one or more embodiments, the gain controller 83a may initialize an attack hold time, based on a reference value THR0, which is less than a first threshold value THR1, while a gain is reduced by an attack. For example, as illustrated in FIG. 12A, the gain controller 83a may initialize the attack hold time when the magnitude of the input signal IN is greater than the reference value THR0. Also, as illustrated in FIG. 12B, the gain controller 83a may initialize the attack hold time when the magnitude of the input signal IN, which is greater than the reference value THR0, decreases less than the reference value THR0. FIGS. 12A and 12B illustrate examples in which the timer 85a includes a down-counter, but example embodiments are limited thereto.

Referring to FIG. 12A, before a time t11, the variable gain amplifier 81a may have a gain reduced by an attack, i.e., a fifth gain GN5. When the magnitude of the input signal IN is greater than the reference value THR0 at the time t11, the gain controller 83a may reset the timer 85a, and accordingly, the timer 85a may have an initial value INI and may measure the attack hold time from the time t11.

When the magnitude of the input signal IN reaches the reference value THR0 again at a time t12, the variable gain amplifier 81a may reset the timer 85a, and accordingly, the timer 85a may have the initial value INI and may measure the attack hold time from the time t12. A value of the timer 85a may reach zero at a time t13, and accordingly, the attack hold time may be measured. At the time t13, the gain controller 83a may identify the elapse of the attack hold time and may start a release. Accordingly, as illustrated in FIG. 12A, the gain of the variable gain amplifier 81a may gradually increase from the fifth gain GN5.

Referring to FIG. 12B, before a time t14, the variable gain amplifier 81a may have the gain reduced by the attack, i.e., the fifth gain GN5. When the magnitude of the input signal IN is greater than the reference value THR0 at the time t14, the gain controller 83a may reset the timer 85a, and may maintain the reset of the timer 85a during a period (i.e., from the time t14 to a time t15) for which the magnitude of the input signal IN is higher than the reference value THR0. When the magnitude of the input signal IN decreases less than the reference value THR0 at the time t15, the gain controller 83a may release the reset of the timer 85a. Accordingly, the timer 85a may measure the attack hold time from the time t15.

When the magnitude of the input signal IN reaches the reference value THR0 again at a time t16, the gain controller 83a may reset the timer 85a, and may maintain the reset of the timer 85a for a period (i.e., from the time t16 to a time t17) for which the magnitude of the input signal IN is higher than the reference value THR0. At the time t17, when the magnitude of the input signal IN decreases less than the reference value THR0, the gain controller 83a may release the reset of the timer 85a. Accordingly, the timer 85a may measure the attack hold time from the time t17. At a time t18, the value of the timer 85a may reach zero, and accordingly, the attack hold time may be measured. At the time t18, the gain controller 83a may identify the elapse of the attack hold time and may start a release. Accordingly, as illustrated in FIG. 12B, the gain of the variable gain amplifier 81a may gradually increase from the fifth gain GN5.

In one or more embodiments, the gain controller 83a may also initialize the attack hold time at any point in time while the magnitude of the input signal IN is greater than the reference value THR0. For example, the gain controller 83a may release the reset of the timer 85a at any point in time between the time t14 and the time t15 (or between the time t16 and the time t17) of FIG. 12B. Accordingly, the timer 85a may start the measurement of the attack hold time between the time t14 and the time t15. Also, in one or more embodiments, the gain controller 83a may initialize the attack hold time at a point in time when a certain time elapses after the magnitude of the input signal IN falls below the reference value THR0. For example, the gain controller 83a may release the reset of the timer 85a at a point in time when a certain time elapses from the time t15 (or the time t17) of FIG. 12B. Accordingly, the timer 85a may start the measurement of the attack hold time after the time t15.

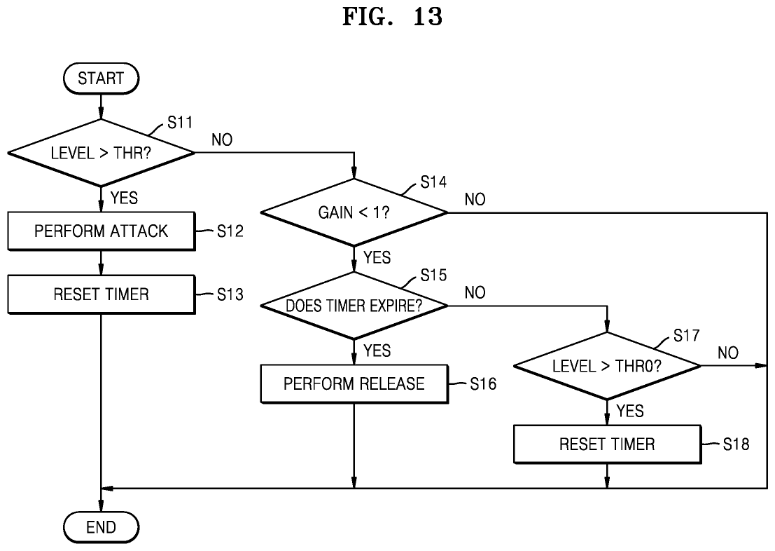

FIG. 13 is a flowchart illustrating a method of adaptively controlling a dynamic range, according to an example embodiment. In detail, the flowchart of FIG. 13 illustrates a method of adaptively controlling a dynamic range, which corresponds to the example described above with reference to FIG. 12B. As illustrated in FIG. 13, the method of adaptively controlling a dynamic range may include a plurality of operations S11 to S18. In one or more embodiments, the method of FIG. 13 may be performed by the gain controller 83a of FIG. 10A, and hereinafter, FIG. 13 will be described with reference to FIG. 10A.

Referring to FIG. 13, in operation S11, whether or not a level of the input signal IN is greater than a threshold value THR may be determined. In one or more embodiments, when the gain controller 83a refers to one threshold value, the threshold value THR of FIG. 13 may correspond to the first threshold value THR1 of FIG. 12B. In one or more embodiments, when the gain controller 83a refers to a plurality of threshold values, the threshold value THR of FIG. 13 may correspond to an upper limit or a lower limit of a range to which a current level of the input signal IN belongs, from among a plurality of ranges defined by the plurality of threshold values. As illustrated in FIG. 13, when the level of the input signal IN is greater than the threshold value THR, operation S12 may be subsequently performed. Otherwise, operation S14 may be subsequently performed.

In operation S12, an attack may be performed. For example, the gain controller 83a may reduce a gain of the variable gain amplifier 81a to attenuate an magnitude of the input signal IN greater than the threshold value THR. In operation S13, a timer may be reset. For example, the attack starts in operation S12, and thus, the gain controller 83a may reset the timer.

In operation S14, the gain may be compared with 1. As illustrated in FIG. 13, when the gain is less than 1, i.e., when the input signal IN is attenuated, operation S15 may be subsequently performed. Otherwise, the method of FIG. 13 may end.

When the gain is less than 1, in operation S15, whether or not the timer 85a expires may be determined. As illustrated in FIG. 13, when the timer 85a expires, i.e., when an attack hold time elapses, a release may be performed in operation S16. When the timer 85a does not expire, i.e., when the attack hold time does not elapse, operation S17 may be subsequently performed.

When the attack hold time does not elapse, in operation S17, the level of the input signal IN may be compared with a reference value THR0. As illustrated in FIG. 13, when the input signal IN is greater than the reference value THR0, in operation S18, the timer 85a may be reset. Otherwise, the method of FIG. 13 may end.

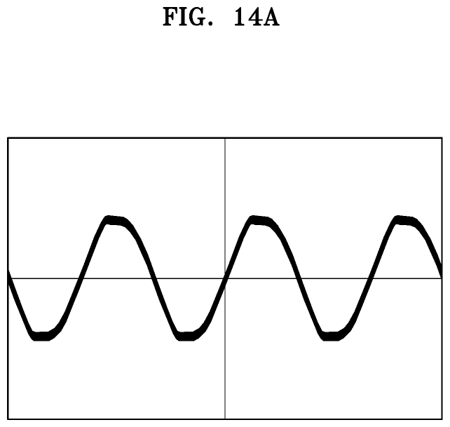

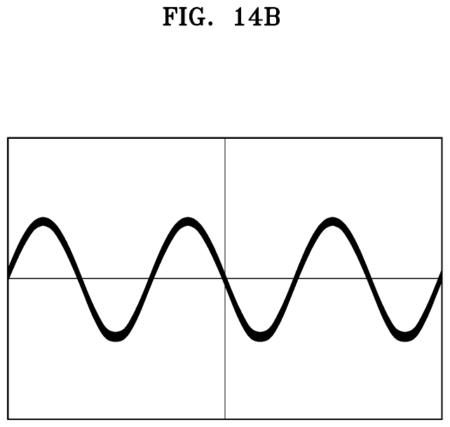

FIGS. 14A and 14B are waveform diagrams illustrating examples of an output signal for a same input signal, according to example embodiments. In detail, the waveform diagram of FIG. 14A illustrates an output waveform when an attack hold time is not applied, and the waveform diagram of FIG. 14B illustrates an output waveform when an attack hold time is applied.

When the attack hold time is not applied, an attack and a release may be repeated, and accordingly, distortion may occur in an output signal. For example, as illustrated in FIG. 14A, the output signal may have a different waveform from an input signal that is a sine wave. When the attack hold time is applied, as illustrated in FIG. 14B, the output signal may have a similar waveform to the input signal that is the sine wave.

FIG. 15 is a block diagram illustrating an example of an audio processing apparatus according to an example embodiment. For example, an audio processing apparatus 130 of FIG. 15 may be an example of audio processing apparatuses as described above. As illustrated in FIG. 15, the audio processing apparatus 130 may include a processor 132 and a memory 134.

The processor 132 may communicate with the memory 134, and may perform at least one operation included in an audio processing method according to an example embodiment by executing a program 134_1 included in the memory 134. The memory 134 may include, as a non-limiting example, any type of memory, which may be accessed by the processor 132, such as random access memory (RAM), read only memory (ROM), a tape, a magnetic disk, an optical disk, a volatile memory, a non-volatile memory, or a combination thereof. In one or more embodiments, the memory 134 may further include a volatile memory device, such as static random access memory (SRAM) or dynamic random access memory (DRAM). In one or more embodiments, the memory 134 may also store information for setting an operation of a gain controller (e.g., 23a of FIG. 2A, 23b of FIG. 2B, 83a of FIG. 10A, or 83b of FIG. 10B).

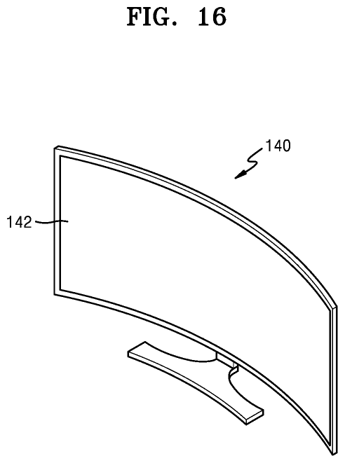

FIG. 16 is a view illustrating an audio system according to an example embodiment. In detail, FIG. 16 illustrates a display apparatus 140 as an example of the audio system 10 of FIG. 1. The display apparatus 140 may include an audio processing apparatus according to example embodiments, and may include a first speaker and a second speaker that output an audio signal, and/or may include ports that output signals provided to the first speaker and the second speaker.

The display apparatus 140 may output, as a non-limiting example, an image signal via a display panel 142 by receiving, like a television or a monitor, an electrical signal including video information. Also, the display apparatus 140 may receive an electrical signal including audio signal, and, as described above with reference to the drawings, may output sounds in which dynamic ranges are effectively limited and distortions are minimized by an audio processing apparatus.

According to an apparatus and method according to example embodiments, distortion of a sound may be minimized by adaptively controlling a dynamic range.

Effects that may be obtained in example embodiments are not limited to the above-mentioned effects, and unmentioned other effects may be clearly derived and understood from the following description by one of ordinary skill in the art to which the example embodiments pertain. In other words, unintended effects according to the implementation of the example embodiments may also be derived by one of ordinary skill in the art from the example embodiments.

As described above, the example embodiments have been disclosed in the drawings and description. The particular terminology used herein is for the purpose of describing the technical spirit of the example embodiments only and is not intended to restrict the meaning of the example embodiments or limit the scope of the disclosure described in the appended claims. Therefore, it will be understood by one of ordinary skill in the art that various modifications and equivalent other embodiments are possible therefrom. Accordingly, the true technical protection scope of the example embodiments should be defined by the technical spirit of the appended claims.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. An audio processing apparatus configured to limit a dynamic range of an audio signal, the audio processing apparatus comprising:
a variable gain amplifier configured to generate an output signal by amplifying or attenuating an input signal;
a level detector configured to detect a level of the input signal or the output signal; and
a gain controller configured to perform an attack and a release based on the level and a plurality of threshold values, wherein
the gain controller is configured to: while performing the attack,
identify a range to which the level belongs, from among a plurality of ranges defined by the plurality of threshold values;
identify an attack intensity corresponding to the identified range, from among a plurality of attack intensities respectively corresponding to the plurality of ranges; and
control a gain of the variable gain amplifier based on the identified attack intensity.

2. The audio processing apparatus of claim 1, wherein
the plurality of threshold values include a first threshold value and a second threshold value that is higher than the first threshold value, and
a first attack intensity corresponding to a first range defined by the first threshold value is lower than a second attack intensity corresponding to a second range that is defined by the second threshold value and is different from the first range.

3. The audio processing apparatus of claim 1, wherein
the plurality of threshold values include a first threshold value and a second threshold value that is higher than the first threshold value, and
a first attack intensity corresponding to a first range defined by the first threshold value is higher than a second attack intensity corresponding to a second range that is defined by the second threshold value and is different from the first range.

4. The audio processing apparatus of claim 1, further comprising an interface unit configured to receive a control signal from an outside, wherein
the gain controller is configured to set, based on the control signal, at least one of the plurality of threshold values and the plurality of attack intensities.

5. The audio processing apparatus of claim 1, further comprising a timer configured to measure an attack hold time, wherein
the gain controller is configured to reset the timer when the attack starts and start the release when the attack hold time is measured.

6. The audio processing apparatus of claim 5, wherein the gain controller is configured to reset the timer when the level is greater than a reference value that is lower than a lowest threshold value from among the plurality of threshold values, while the gain is reduced by the attack.

7. The audio processing apparatus of claim 1, wherein the level detector is configured to detect the level that is proportional to an instantaneous peak of the input signal or the output signal.

8. An audio processing apparatus configured to limit a dynamic range of an audio signal, the audio processing apparatus comprising:
a variable gain amplifier configured to generate an output signal by amplifying or attenuating an input signal;
a level detector configured to detect a level of the input signal or the output signal; and
a gain controller configured to perform an attack and a release based on the level and predefined at least one function, wherein
the gain controller is configured to, while performing the attack,
calculate an attack intensity corresponding to the level, based on the at least one function, and
control a gain of the variable gain amplifier based on a calculated attack intensity.

9. The audio processing apparatus of claim 8, wherein the gain controller is configured to: while performing the attack,
identify a range to which the level belongs, from among a plurality of ranges defined by a plurality of threshold values;
identify a function corresponding to the identified range, from among a plurality of predefined functions respectively corresponding to the plurality of ranges; and
calculate the attack intensity corresponding to the level, based on the identified function.

10. The audio processing apparatus of claim 8, further comprising an interface unit configured to receive a control signal from an outside, wherein
the gain controller is configured to set at least one coefficient included in the at least one function, based on the control signal.

11. The audio processing apparatus of claim 8, further comprising a timer configured to measure an attack hold time, wherein
the gain controller is configured to reset the timer when the attack starts and start the release when the attack hold time is measured.

12. The audio processing apparatus of claim 11, wherein the gain controller is configured to reset the timer when the level is greater than a reference value that is lower than a lowest threshold value from among a plurality of threshold values, while the gain is reduced by the attack.

13. The audio processing apparatus of claim 8, wherein the level detector is configured to detect the level that is proportional to an instantaneous peak of the input signal or the output signal.

14. An audio processing apparatus configured to limit a dynamic range of an audio signal, the audio processing apparatus comprising:
a variable gain amplifier configured to generate an output signal by amplifying or attenuating an input signal;
a level detector configured to detect a level of the input signal or the output signal;
a timer configured to measure an attack hold time; and
a gain controller configured to perform an attack and a release based on the level and at least one threshold value, wherein
the gain controller is configured to reset the timer when the attack starts and start the release when the attack hold time is measured.

15. The audio processing apparatus of claim 14, wherein the gain controller is configured to reset the timer when the level is greater than a reference value that is lower than a lowest threshold value from among the at least one threshold value, while the gain is reduced by the attack.

16. The audio processing apparatus of claim 15, further comprising an interface unit configured to receive a control signal from an outside, wherein
the gain controller is configured to set at least one of the attack hold time and the reference value based on the control signal.

17. The audio processing apparatus of claim 14, wherein the level detector is configured to detect the level that is proportional to an instantaneous peak of the input signal or the output signal.
